(19) United States
(12) Patent Application Publication
(10) Pub. No.: US 2009/0065905 A1
(43) Pub. Date: Mar. 12, 2009

(54) Conductive metal structure applied to a module IC and method of manufacturing the same

(76) Inventors: Chung-Er Huang, Taipei (TW); Shih-Meng Luo, Taipei (TW); Sheng-Wen Chen, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/076,966

(22) Filed: Mar. 26, 2008

(30) Foreign Application Priority Data
Sep. 7, 2007 (TW) 96133536

(51) Int. Cl. H01L 23/488; H01L 21/44

(52) U.S. Cl. 257/621; 438/614; 257/E23.023; 257/E21.476

(57) ABSTRACT

A conductive metal structure applied to a module IC includes a wafer, a first insulating unit, and a first conductive unit. The wafer has a main body and a through hole passing through the main body. The first insulating unit has a first inner insulating layer formed on an inner surface of the through hole and a first outer insulating layer that is extended from the first inner insulating layer and is formed on a first bottom surface of the main body. The first conductive unit has a first inner conductive layer formed on the first inner insulating layer and at least one first conductive pad formed on the first outer insulating layer. The present invention integrates semiconductor technologies of etching and deposition and combines them with the development of the module IC in order to provide a conductive metal structure that has lower cost and is manufactured easily.

### BACKGROUND OF THE INVENTION

1. Field of the Invention

The present invention relates to a conductive metal structure and a method of manufacturing the same, and particularly relates to a conductive metal structure applied to a module IC (Integrated Circuit) and a method of manufacturing the same.

2. Description of the Related Art

As integrated circuit technology has been rapidly developing, a variety of devices using the technology are developed continuously. Because the functions of the devices are rapidly added, most devices are implemented in a modular way. However, while the functions of the devices can be increased by integrating a lot of functional modules, the design of a multiple function device with small dimensions is still difficult.

In the semiconductor manufacturing process, a high level technology is used to manufacture a small chip or component. Therefore, the module manufacturer can design a functional module with small dimensions, and the device can be efficiently and fully developed.

Currently, most modules use the printed circuit board (PCB), Flame Retardant 4 (FR-4), or Bismaleimide Triazine (BT) substrate as a carrier. All chips and components are mounted onto the surface of the carrier by using a surface mounting technology (SMT). Therefore, the substrate is merely used as a carrier and is used for connecting the circuit. The structure of the substrate is a multiple-layered structure and is only used for the circuit layout.

In radio frequency (RF) system modules for example, in order to have multiple functions, a wireless local area (WLAN) module is usually integrated with a Bluetooth module or a global positioning system (GPS) module. However, the required peripheral circuits increases. When all components for each of the circuits are mounted onto the substrate, the dimension of the whole module increases. At the same time, it is difficult for the designer to insulate the circuit within the substrate from interferences from outside signals, and the characteristic of the circuit may be affected.

In the prior art, the technologies of IPD (Integrated Passive Device) and IPC (Integrated Peripheral Circuit) are two methods for decreasing the size of the module by mounting integrated circuits on two sides of the wafer. To connect the two sides of the wafer the following method is usually used: forming a through hole passing through a wafer, and filling the through hole with metal to form a pad. However, this method incurs high costs, and it is difficult to completely fill the through hole with the metal.

### SUMMARY OF THE INVENTION

One particular aspect of the present invention is to provide a conductive metal structure applied to a module IC and a method of manufacturing the same. A module IC using a silicon wafer as a carrier board is manufactured by a conductive metal structure that is used to conduct an upper circuit and a lower circuit of the module IC. The present invention integrates semiconductor technologies of etching and deposition and combines them with the development of the module IC in order to provide a conductive metal structure that has lower cost and is manufactured easily.

In order to achieve the above-mentioned aspects, the present invention provides a conductive metal structure applied to a module IC, including: a wafer, a first insulating unit, and a first conductive unit. The wafer has a main body and at least one through hole passing through the main body. The first insulating unit has a first inner insulating layer formed on an inner surface of the at least one through hole and a first outer insulating layer that is extended from the first inner insulating layer and is formed on a first bottom surface of the main body. The first conductive unit has a first inner conductive layer formed on the first inner insulating layer and at least one first conductive pad formed on the first outer insulating layer.

In order to achieve the above-mentioned aspects, the present invention provides a conductive metal structure applied to a module IC, including: a wafer, a first insulating unit, and a first conductive unit. The wafer has a main body and at least one through hole passing through the main body. The first insulating unit has a first inner insulating layer formed on an inner surface of the at least one through hole and a first outer insulating layer that is extended from the first inner insulating layer and is formed on a first bottom surface of the main body. The first conductive unit has a first inner conductive layer formed on the first inner insulating layer and a first outer conductive layer formed on the first outer insulating layer. The at least one first conductive body is disposed on the first outer conductive layer to form a conductive pad.

In order to achieve the above-mentioned aspects, the present invention provides a method of manufacturing a conductive metal structure applied to a module IC, including: firstly, providing a wafer that has a main body and at least one through hole passing through the main body; forming a first inner insulating layer on an inner surface of the at least one through hole and forming a first outer insulating layer that is extended from the first inner insulating layer and is formed on a first bottom surface of the main body at the same time; forming a first inner conductive layer on the first inner insulating layer and forming a first outer conductive layer on the first outer insulating layer at the same time; finally, removing one part of the first outer conductive layer to form at least one first conductive pad on the first outer insulating layer or disposing at least one first conductive body on the first outer conductive layer to form a conductive pad, wherein the at least one first conductive body is a solder ball.

Therefore, the conductive metal structure applied to a module IC of the present invention has some advantages, as follows:

1. The present invention takes a wafer such a silicon wafer as a carrier board and etches the wafer to form at least one through hole for connecting an upper circuit and a lower circuit of a module IC. The module IC has one or more passive components or active components disposed on or in the main body of the wafer.

2. An oxide layer such as SiO2 is formed in the inner surface of the through hole to be an insulating layer such as the first insulating unit in order to insulate the wafer from a metal layer such as the first conductive unit.

3. The metal layer is formed on the oxide layer, so the metal layer does not need to fill the through hole completely and the thickness of the metal layer is thin. The function of the metal layer is to conduct the upper circuit and the lower circuit of the module IC.

4. A bottom side of the metal layer such as the first outer conductive layer is etched to form a conductive metal pad such as the first conductive pad.

5. A solder ball is disposed on the bottom side of the metal layer to do a conductive metal pad such as the first conductive body.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a flowchart of a method of manufacturing a conductive metal structure applied to a module IC according to the first embodiment of the present invention;

FIGS. 1A to 1F are cross-sectional, schematic views of a conductive metal structure applied to a module IC according to the first embodiment of the present invention, at different stages of the manufacturing process, respectively;

FIG. 2 is a flowchart of a method of manufacturing a conductive metal structure applied to a module IC according to the second embodiment of the present invention;

FIGS. 2A to 2F are cross-sectional, schematic views of a conductive metal structure applied to a module IC according to the second embodiment of the present invention, at different stages of the manufacturing process, respectively; and

FIG. 3 is an assembly, schematic view of two conductive metal structures of the first and the second embodiments of the present invention.

### DETAILED DESCRIPTION OF THE PREFERRED EMBODIMENTS

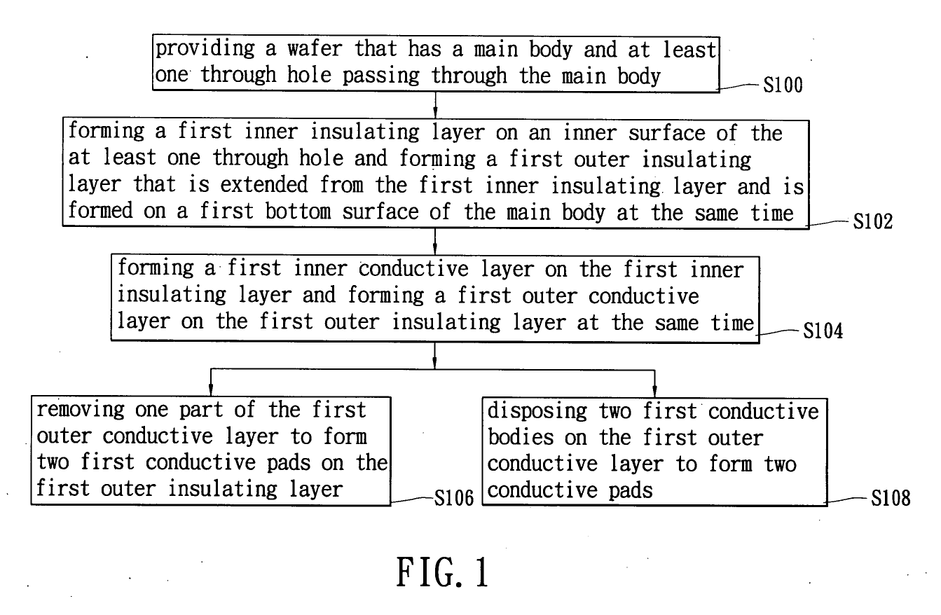

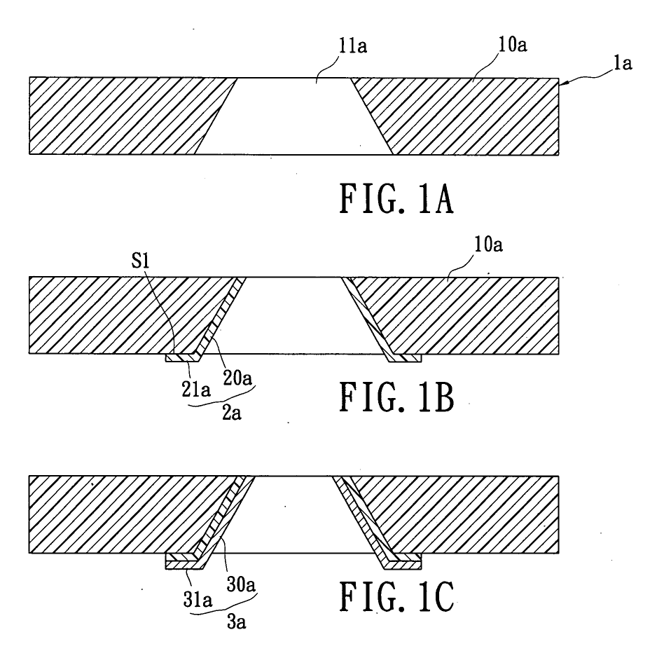

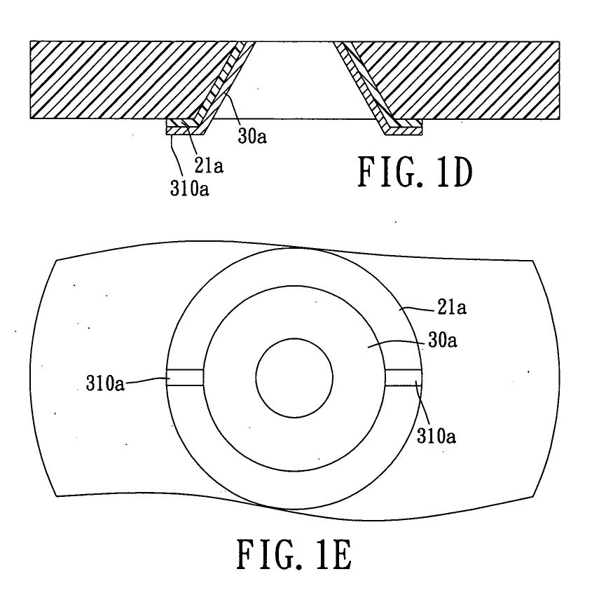

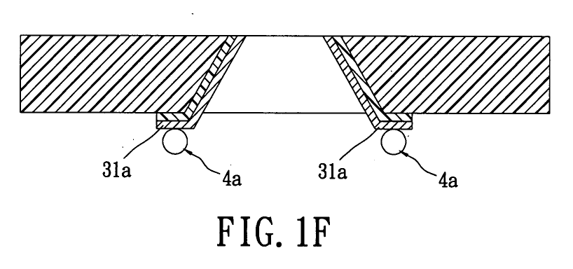

Referring to FIGS. 1 and 1A to 1F, FIG. 1 shows a flowchart of a method of manufacturing a conductive metal structure applied to a module IC according to the first embodiment of the present invention, and FIGS. 1A to 1F show cross-sectional, schematic views of a conductive metal structure applied to a module IC according to the first embodiment of the present invention, at different stages of the manufacturing process, respectively.

The first embodiment of the present invention provides a method of manufacturing a conductive metal structure applied to a module IC, including:

Step S100 (referring to FIGS. 1 and 1A) is providing a wafer 1a that has a main body 10a and at least one through hole 11a passing through the main body 10a. In addition, the wafer 1a can be a silicon wafer, and the at least one through hole 11a is penetrated via wet or dry etching.

Step S102 (referring to FIGS. 1 and 1B) is forming a first inner insulating layer 20a on an inner surface of the at least one through hole 11a and forming a first outer insulating layer 21a that is extended from the first inner insulating layer 20a and is formed on a first bottom surface S1 of the main body 10a at the same time. In addition, both the first inner insulating layer 20a and the first outer insulating layer 21a are oxide layers, and both the first inner insulating layer 20a and the first outer insulating layer 21a are formed via oxidation or deposition processes. The first inner insulating layer 20a and the first outer insulating layer 21a are combined together to form a first insulating unit 2a.

Step S104 (referring to FIGS. 1 and 1C) is forming a first inner conductive layer 30a on the first inner insulating layer 20a and forming a first outer conductive layer 31a on the first outer insulating layer 21a at the same time. In addition, both the first inner conductive layer 30a and the first outer conductive layer 31a can be metal layers, and both the first inner conductive layer 30a and the first outer conductive layer 31a are formed via electroplating, deposition, or sputtering processes. The first inner conductive layer 30a and the first outer conductive layer 31a are combined together to form a first conductive unit 3a.

After the step of S104, the first embodiment of the present invention provides two methods for forming conductive pad according to designer's needs, as follows:

First forming method (referring to FIGS. 1, 1D and 1E, and FIG. 1E being a bottom view of FIG. 1D) is removing one part of the first outer conductive layer 31a to form two first conductive pads 310a on the first outer insulating layer 21a (step S106). In addition, one part of the first outer conductive layer 31a is removed via etching. Moreover, the number of first conductive pads 310a does not use to limit the present invention. In other words, one or more first conductive pads 310a are protected in the present invention.

Second forming method (referring to FIGS. 1 and 1F) is disposing two first conductive bodies 4a on the first outer conductive layer 31a to form two conductive pads (step S108). In addition, the first conductive body 4a can be a solder ball. Moreover, the number of first conductive bodies 4a does not use to limit the present invention. In other words, one or more first conductive body 4a are protected in the present invention.

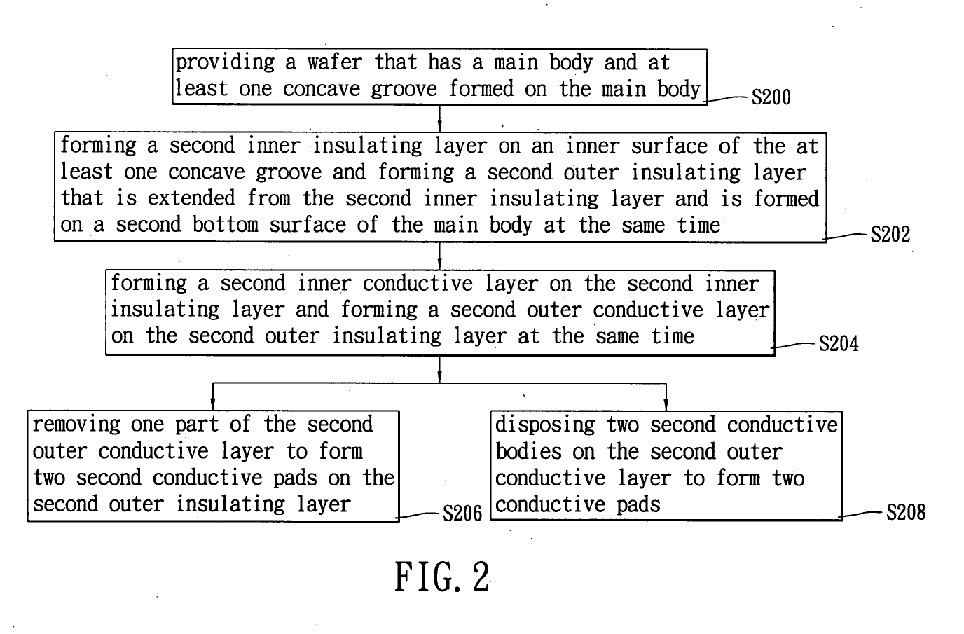

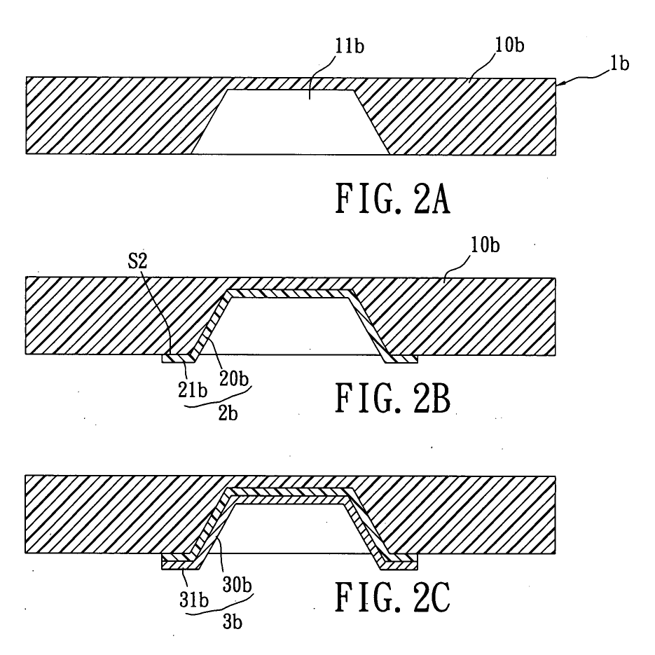

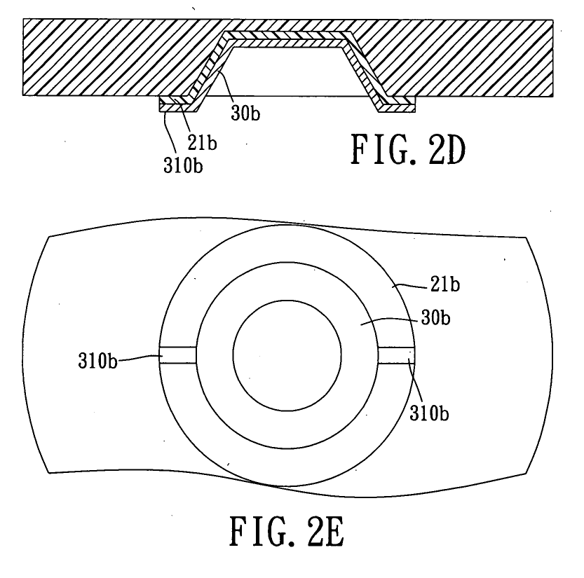

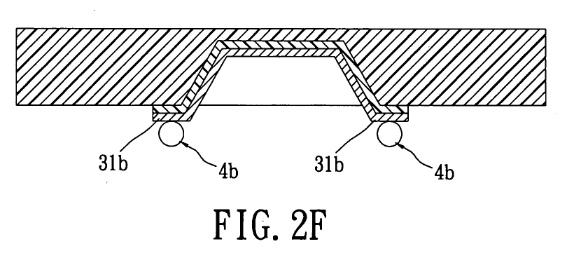

Referring to FIGS. 2 and 2A to 2F, FIG. 2 shows a flowchart of a method of manufacturing a conductive metal structure applied to a module IC according to the second embodiment of the present invention, and FIGS. 2A to 2F show cross-sectional, schematic views of a conductive metal structure applied to a module IC according to the second embodiment of the present invention, at different stages of the manufacturing process, respectively.

The second embodiment of the present invention provides a method of manufacturing a conductive metal structure applied to a module IC, including:

Step S200 (referring to FIGS. 2 and 2A) is providing a wafer 1b that has a main body 10b and at least one concave groove 11b formed on the main body 10b. In addition, the wafer 1b can be a silicon wafer, and the at least one concave groove 11b is penetrated via wet or dry etching.

Step S202 (referring to FIGS. 2 and 2B) is forming a second inner insulating layer 20b on an inner surface of the at least one concave groove 11b and forming a second outer insulating layer 21b that is extended from the second inner insulating layer 20b and is formed on a second bottom surface S2 of the main body 10b at the same time. In addition, both the second inner insulating layer 20b and the second outer insulating layer 21b are oxide layers, and both the second inner insulating layer 20b and the second outer insulating layer 21b are formed via oxidation or deposition processes. The second inner insulating layer 20b and the second outer insulating layer 21b are combined together to form a second insulating unit 2b.

Step S204 (referring to FIGS. 2 and 2C) is forming a second inner conductive layer 30b on the second inner insulating layer 20b and forming a second outer conductive layer 31b on the second outer insulating layer 21b at the same time. In addition, both the second inner conductive layer 30b and the second outer conductive layer 31b can be metal layers, and both the second inner conductive layer 30b and the second outer conductive layer 31b are formed via electroplating, deposition, or sputtering processes. The second inner conductive layer 30b and the second outer conductive layer 31b are combined together to form a second conductive unit 3b.

After the step of S204, the second embodiment of the present invention provides two methods for forming conductive pad according to designer's needs, as follows:

First forming method (referring to FIGS. 2, 2D and 2E, and FIG. 2E being a bottom view of FIG. 2D) is removing one part of the second outer conductive layer 31b to form two second conductive pads 310b on the second outer insulating layer 21b (step S206). In addition, one part of the second outer conductive layer 31b is removed via etching. Moreover, the number of second conductive pads 310b does not use to limit the present invention. In other words, one or more second conductive pads 310b are protected in the present invention.

Second forming method (referring to FIGS. 2 and 2F) is disposing two second conductive bodies 4b on the second outer conductive layer 31b to form two conductive pads (step S208). In addition, the second conductive body 4b can be a solder ball. Moreover, the number of second conductive bodies 4b does not use to limit the present invention. In other words, one or more second conductive body 4b are protected in the present invention.

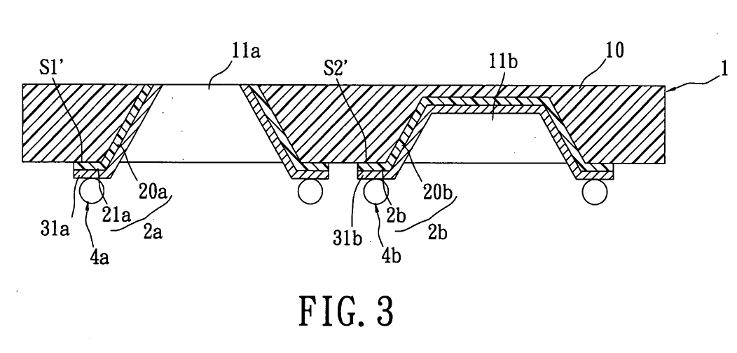

FIG. 3 shows an assembly, schematic view of two conductive metal structures of the first and the second embodiments of the present invention. The conductive metal structure of the first embodiment and the conductive metal structure of the second embodiment can be used separately or can be manufactured on the same silicon wafer. In other words, such as using the second conductive bodies (4a, 4b), the conductive metal structures of the first embodiment and the second embodiment can be formed in a main body 10 of a wafer 1, and the main body 10 also has a first bottom surface S1′ and a second bottom surface S2′.

In conclusion, the conductive metal structure applied to a module IC of the present invention has some advantages, as follows:

1. The present invention takes a wafer 1a or 1b such a silicon wafer as a carrier board and etches the wafer 1a or 1b to form at least one through hole 11a or concave groove 11b for connecting an upper circuit and a lower circuit of a module IC. The module IC has one or more passive components or active components disposed on or in the main body 10a of the wafer 1.

2. An oxide layer such as SiO2 is formed in the inner surface of the through hole 11a or the concave groove 11b to be an insulating layer such as the first insulating unit 2a or the second insulating unit 2b in order to insulate the wafer 1a or 1b from a metal layer such as the first conductive unit 3a or the second conductive unit 3b.

3. The metal layer is formed on the oxide layer, so the metal layer does not need to fill the through hole 11a or the concave groove 11b completely and the thickness of the metal layer is thin. The function of the metal layer is to conduct the upper circuit and the lower circuit of the module IC.

4. A bottom side of the metal layer such as the first outer conductive layer 31a and the second outer conductive layer 31b is etched to form a conductive metal pad such as the first conductive pad 310a and the second conductive pad 310b.

5. A solder ball is disposed on the bottom side of the metal layer to do a conductive metal pad such as the first conductive body 4a and the second conductive body 4b.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A conductive metal structure applied to a module IC, comprising:
a wafer having a main body and at least one through hole passing through the main body;
a first insulating unit having a first inner insulating layer formed on an inner surface of the at least one through hole and a first outer insulating layer that is extended from the first inner insulating layer and is formed on a first bottom surface of the main body; and
a first conductive unit having a first inner conductive layer formed on the first inner insulating layer and at least one first conductive pad formed on the first outer insulating layer.

2. The conductive metal structure as claimed in claim 1, wherein the wafer is a silicon wafer, both the first inner insulating layer and the first outer insulating layer are oxide layers, and both the first inner conductive layer and the at least one first conductive pad are metal layers.

3. The conductive metal structure as claimed in claim 1, further comprising:
at least one concave groove formed on the main body;
a second insulating unit having a second inner insulating layer formed on an inner surface of the at least one concave groove and a second outer insulating layer that is extended from the second inner insulating layer and is formed on a second bottom surface of the main body; and
a second conductive unit having a second inner conductive layer formed on the second inner insulating layer and at least one second conductive pad formed on the second outer insulating layer.

4. The conductive metal structure as claimed in claim 3, wherein both the second inner insulating layer and the second outer insulating layer are oxide layers, and both the second inner conductive layer and the at least one second conductive pad are metal layers.

5. A conductive metal structure applied to a module IC, comprising:
a wafer having a main body and at least one through hole passing through the main body;
a first insulating unit having a first inner insulating layer formed on an inner surface of the at least one through hole and a first outer insulating layer that is extended from the first inner insulating layer and is formed on a first bottom surface of the main body;
a first conductive unit having a first inner conductive layer formed on the first inner insulating layer and a first outer conductive layer formed on the first outer insulating layer; and
at least one first conductive body disposed on the first outer conductive layer to form a conductive pad.

6. The conductive metal structure as claimed in claim 5, wherein the wafer is a silicon wafer, both the first inner insulating layer and the first outer insulating layer are oxide layers, both the first inner conductive layer and the first outer conductive layer are metal layers, and the at least one first conductive body is a solder ball.

7. The conductive metal structure as claimed in claim 5, further comprising:
at least one concave groove formed on the main body;
a second insulating unit having a second inner insulating layer formed on an inner surface of the at least one concave groove and a second outer insulating layer that is extended from the second inner insulating layer and is formed on a second bottom surface of the main body;
a second conductive unit having a second inner conductive layer formed on the second inner insulating layer and a second outer conductive layer formed on the second outer insulating layer; and
at least one second conductive body disposed on the second outer conductive layer to form a conductive pad.

8. The conductive metal structure as claimed in claim 7, wherein both the second inner insulating layer and the second outer insulating layer are oxide layers, both the second inner conductive layer and the second outer conductive layer are metal layers, and the at least one second conductive body is a solder ball.

9. A method of manufacturing a conductive metal structure applied to a module IC, comprising:
providing a wafer that has a main body and at least one through hole passing through the main body;
forming a first inner insulating layer on an inner surface of the at least one through hole and forming a first outer insulating layer that is extended from the first inner insulating layer and is formed on a first bottom surface of the main body at the same time; and
forming a first inner conductive layer on the first inner insulating layer and forming a first outer conductive layer on the first outer insulating layer at the same time.

10. The method as claimed in claim 9, wherein the at least one through hole is penetrated via wet or dry etching.

11. The method as claimed in claim 9, wherein the wafer is a silicon wafer, both the first inner insulating layer and the first outer insulating layer are oxide layers, and both the first inner conductive layer and the first outer conductive layer are metal layers.

12. The method as claimed in claim 9, wherein both the first inner insulating layer and the first outer insulating layer are formed via oxidation or deposition processes, and both the first inner conductive layer and the first outer conductive layer are formed via electroplating, deposition, or sputtering processes.

13. The method as claimed in claim 9, further comprising: removing one part of the first outer conductive layer to form at least one first conductive pad on the first outer insulating layer.

14. The method as claimed in claim 9, further comprising: disposing at least one first conductive body on the first outer conductive layer to form a conductive pad, wherein the at least one first conductive body is a solder ball.

15. The method as claimed in claim 9, further comprising:
forming at least one concave groove on the main body;
forming a second inner insulating layer on an inner surface of the at least one concave groove and forming a second outer insulating layer that is extended from the second inner insulating layer and is formed on a second bottom surface of the main body at the same time; and
forming. a second inner conductive layer on the second inner insulating layer and forming a second outer conductive layer on the second outer insulating layer.

16. The method as claimed in claim 15, wherein the at least one concave groove is formed via wet or dry etching.

17. The method as claimed in claim 15, wherein both the second inner insulating layer and the second outer insulating layer are oxide layers, and both the second inner conductive layer and the second outer conductive layer are metal layers.

18. The method as claimed in claim 15, wherein both the second inner insulating layer and the second outer insulating layer are formed via oxidation or deposition processes, and both the second inner conductive layer and the second outer conductive layer are formed via electroplating, deposition, or sputtering processes.

19. The method as claimed in claim 15, further comprising: removing one part of the second outer conductive layer to form at least one second conductive pad on the second outer insulating layer.

20. The method as claimed in claim 15, further comprising: disposing at least one second conductive body on the second outer conductive layer to form a conductive pad, wherein the at least one second conductive body is a solder ball.
